(19) United States
(12) Patent Application Publication
(10) Pub. No.: US 2025/0374643 A1
(43) Pub. Date: Dec. 4, 2025

(54) GaN HEMT WITH LOW THRESHOLD VOLTAGE SHIFT USING A HOLE INJECTOR/COLLECTOR

(71) Applicant: Efficient Power Conversion Corporation, El Segundo, CA (US)

(72) Inventors: Victor Estrada, Los Angeles, CA (US); Robert Strittmatter, Tujunga, CA (US); Jianjun Cao, Torrance, CA (US); Robert Beach, La Crescenta, CA (US); Muskan Sharma, Torrance, CA (US); Alexander Lidow, Topanga, CA (US); Wen-Chia Liao, Torrance, CA (US); Massimo Grasso, Trivolzio (PV) (IT); Sergio Morini, Pavia (IT)

(73) Assignee: Efficient Power Conversion Corporation, El Segundo, CA (US)

(21) Appl. No.: 19/301,309

(22) Filed: Aug. 15, 2025

Related U.S. Application Data
(63) Continuation-in-part of application No. 19/207,772, filed on May 14, 2025.
Application No. 19/207,772 is a continuation-in-part of application No. 18/436,352, filed on Feb. 8, 2024.
(60) Provisional application No. 63/483,997, filed on Feb. 9, 2023.
(60) Provisional application No. 63/504,084, filed on May 24, 2023.
(60) Provisional application No. 63/710,910, filed on Oct. 23, 2024.
(60) Provisional application No. 63/793,016, filed on Apr. 23, 2025.

(51) Int. Cl. H10D 64/62; H10D 30/47; H10D 62/85; H10D 89/00

(52) U.S. Cl. CPC H10D 64/62; H10D 30/475; H10D 62/8503; H10D 89/215

(57) ABSTRACT

This invention pertains to the design of a novel Gallium Nitride (GaN) High Electron Mobility Transistor (HEMT) with multiple metal contacts to a single contiguous p-GaN island. The invention encompasses various embodiments which introduce innovative mechanisms for threshold voltage (Vth) control through hole injection and removal.

### CROSS-REFERENCE TO RELATED APPLICATIONS

This application is a continuation-in-part of U.S. application Ser. No. 19/207,722, filed May 14, 2025, which is a continuation-in-part of U.S. application Ser. No. 18/436,352, filed Feb. 8, 2024, which claims priority to provisional Application No. 63/483,997, filed Feb. 9, 2023, and provisional Application No. 63/504,084, filed May 24, 2023. This application also claims the benefit of U.S. Provisional Application No. 63/710,910 filed Oct. 23, 2024, and U.S. Provisional Application No. 63/793,016, filed Apr. 23, 2025. All of the disclosures are incorporated by reference herein in their entireties.

### FIELD OF THE INVENTION

The present invention relates to the field of column III nitride transistors such as gallium nitride (GaN) transistors.

### BACKGROUND OF THE INVENTION

Gallium nitride (GaN) semiconductor devices are increasingly desirable for power semiconductor devices because of their ability to carry large current and support high voltages. Development of these devices has generally been aimed at high power/high frequency applications. Devices fabricated for these types of applications are based on general device structures that exhibit high electron mobility and are referred to variously as heterojunction field effect transistors (HFET), high electron mobility transistors (HEMT), or modulation doped field effect transistors (MODFET).

A GaN HEMT device includes a nitride semiconductor with at least two nitride layers. Different materials formed on the semiconductor or on a buffer layer cause the layers to have different band gaps. The different material in the adjacent nitride layers also causes polarization, which contributes to a conductive two-dimensional electron gas (2DEG) region near the junction of the two layers, specifically in the layer with the narrower band gap.

The nitride layers that cause polarization typically include a barrier layer of AlGaN adjacent to a layer of GaN to include the 2DEG, which allows charge to flow through the device. This barrier layer may be doped or undoped. Because the 2DEG region exists under the gate at zero gate bias, nitride devices are inherently normally on, or depletion mode devices. If the 2DEG region is depleted, i.e. removed, below the gate at zero applied gate bias, the device is an enhancement mode device. Enhancement mode devices are normally off and are desirable because of the added safety they provide and because they are easier to control with simple, low-cost drive circuits. An enhancement mode device requires a positive bias applied at the gate in order to conduct current. Transistors have a voltage threshold (Vth), which is the minimum voltage needed to turn the transistor on and allow current to flow between the source and drain terminals.

FIG. 1A illustrates an enhancement mode GaN transistor disclosed in U.S. Pat. No. 8,890,168, the entire disclosure of which is incorporated herein by reference. The GaN device of FIG. 1A includes a silicon substrate 11, transition layers 12, undoped GaN buffer material 13, undoped AlGaN barrier layer 14, p-type GaN gate material 15, gate metal 17, dielectric material 18, drain ohmic contact 19, and source ohmic contact 20.

FIG. 1B shows a conventional GaN gate GaN HEMT device, showing electrons 5 that have entered the gate material 15 and are trapped inside the gate GaN material 15. As shown, some electrons 5 might enter and get trapped on the sidewalls of the gate material 15, or enter and get trapped in the bulk (central) area of the gate material 15, as shown by the dashed lines. This dynamic charge trapping causes the Vth of the HEMT to be unstable and fluctuate, which is undesirable. As electrons enter and become trapped in the gate material 15, the voltage threshold increases dynamically.

Referring to FIG. 2, like all enhancement mode GaN transistors, the GaN device of FIG. 1 conducts current from drain 19 to source 20 when the drain is biased positive with respect to the source, and a positive voltage is applied to the gate 30. However, as indicated in FIG. 1, under a high voltage drain bias, holes generated in the drain region (or other regions of the device where high electric fields exist) drift toward the gate and become trapped or confined within the p-type GaN gate layer. The arrow “a” illustrates holes above the front barrier moving toward the gate material, arrow “b” illustrate holes under the front barrier which partially move toward the gate material directly below the gate, and arrow “c” shows holes under the front barrier which move toward the source. Under gate bias, hole generation may also occur in the gate region itself. The accumulation of these holes in the gate material under the gate metal, over time, disadvantageously causes lower threshold voltage and higher drain-to-source leakage current when the device is off.

FIGS. 3A, 3B are reproduced from Giorgino et al., “Study of Magnesium Activation Effect on Pinch-Off Voltage of Normally-Off p-GaN HEMTs for Power Applications,” Crystals 2023, Vol. 13, No. 3, 1309. Giorgino discloses and compares: (1) a single-RTP process, characterized by Mg doping during the epitaxial growth of the GaN cap and a standard Rapid Thermal Processing (RTP) for Mg activation (temperature in the range of 700-850° C. for a time duration of 1-10 min), performed after the p-GaN growth; and (2) a multiple-RTP process, featuring Mg doping during the epitaxial growth of the GaN cap, but with improved Mg activation by performing the RTP activation process several times during the device process flow. As shown in FIG. 3A, the multiple RTA process results in the p-GaN gate material having two regions, a depleted region of p-GaN that has no mobile holes, and an undepleted region of p-GaN that has mobile holes (the single RTP process has a depleted region only, and no undepleted region). The presence of mobile holes in the p-GaN leads to higher gate capacitance, as shown in FIG. 3B. Giorginio et al. recognize additional drawbacks to having mobile holes in the p-GaN gate material, namely higher gate leakage; higher hysteresis and voltage threshold (Vth) instability; and increased current collapse in dynamic conditions.

### SUMMARY OF THE INVENTION

For all of the above-noted reasons, it would be desirable to have an enhancement mode GaN transistor in which the Vth is stable and does not change over time. It would be further desirable to provide an enhancement mode GaN transistor in which holes in the GaN gate material are continuously or periodically removed, keeping the charge state of the gate essentially constant over time.

The present invention advantageously provides an enhancement mode GaN transistor with a feature that attracts holes in the GaN gate material under the gate electrode metal, and continuously removes them from the gate material. The holes are removed from the gate material by any of several transport processes, including but not limited to: (1) recombination of the holes with electrons, thereby neutralizing the holes; (2) thermionic emission of holes over a Schottky metal contact, preferably with the contact biased at a negative voltage to enhance emission; and (3) tunneling or injection of holes across an ohmic contact. Using any of the above, holes are removed from the gate material, such that the device is capable of withstanding higher voltage.

The GaN gate material has two overlaying electrodes: a gate electrode and a hole injector/collector electrode. The hole injector/collector electrode may make either a Schottky or an ohmic contact to the underlying GaN gate material. The hole injector/collector electrode is disposed at the top surface of the GaN gate material and/or can extend into or through the GaN gate material. The GaN gate material between the hole injector/collector electrode and the gate electrode may be thinner than the GaN gate material under the gate electrode.

In a first injection operational mode, to depopulate traps, a positive bias is applied to the hole injector/collector electrode to inject holes, thereby resetting the voltage threshold Vth to pre-shift levels. The holes accumulating within the gate further decrease the Vth below the desired threshold.

In a second removal operational mode, to restore the original Vth, a negative bias is applied to the hole injector/collector electrode, effectively removing excess holes from the gate. Holes under the gate are attracted and recombine with electrons supplied by the negative voltage connected to the hole injector/collector electrode, thereby substantially eliminating the holes in the GaN gate material.

This dual action process results in a gate with depopulated traps and removed excess holes, thereby recovering the Vth to pre-shift levels. The negative and positive voltage biases supplied to the hole injector/collector electrode can be generated by a negative voltage generating circuit implemented in GaN and integrated with the enhancement mode GaN transistor. In some embodiments, the negative and positive voltage supplied to the hole injector/collector electrode can be generated by a silicon IC co-packaged with the GaN device of this invention. In other embodiments, the negative and positive voltages supplied to the hole injector/collector electrode can be supplied externally by the user.

In another embodiment of the invention, another hole injector/collector contact is made to the GaN gate material, enabling continuous hole injection and removal. By applying a positive bias to one contact, holes are injected, while a negative bias applied to a third contact removes holes. This simultaneous injection and removal process ensures trap depopulation without unnecessary hole accumulation within the gate.

### BRIEF DESCRIPTION OF THE DRAWINGS

The features, objects, and advantages of the present invention will become more apparent from the detailed description set forth below when taken in conjunction with the drawings in which like reference characters identify correspondingly throughout and wherein:

FIG. 1A shows a typical GaN transistor.

FIG. 1B shows a cross-section of the gate of FIG. 1A, with electrons trapped in the gate material.

FIG. 2 shows a cross-section of the prior art GaN Gate HEMT of FIG. 1A.

FIGS. 3A, 3B illustrate the effect of mobile holes in the gate material.

FIG. 4A shows a top view of a first embodiment of the present invention with a hole injector/collector contact connected to the main gate of the transistor.

FIG. 4B shows a cross-section side view of another embodiment.

FIG. 5A shows a cross-section taken along line A-A of FIG. 5B.

FIG. 5B shows a closer top view of the first embodiment, FIG. 4A, of the present invention.

FIG. 5C is a cross-section taken along lines B-B of FIG. 5B.

FIGS. 6A, 6B show an alternative layout in which the gate line forms a racetrack surrounding the drain contact.

FIG. 6C illustrates a single hole injector/collector electrode.

FIG. 6D illustrates a single hole injector/collector electrode for hole injection in the gate.

FIG. 6E illustrates the use of a single hole injector/collector electrode for hole removal in the gate.

FIG. 6F illustrates a threshold voltage shift as a function of gate stress time.

FIG. 6G is a top view of another embodiment of the present invention with two hole injector/collector electrodes.

FIG. 6H is a cross-sectional view of the device showing hole movement.

FIGS. 7A-7E show various possible connections of the hole injector/collector metal to the GAN gate material.

FIG. 8A shows a depletion mode GaN FET configured as a linear supply in the negative voltage generating circuit of the present invention.

FIG. 8B shows a voltage generating circuit.

FIG. 9 shows a depletion mode GaN FET in the sensor circuitry of the voltage generating circuit.

FIG. 10 is a circuit schematic of the charge pump circuitry of the negative voltage generating circuit.

FIG. 11A is a circuit schematic of the entire negative voltage generating circuit.

FIG. 11B shows the circuit coupled to the hole injector/collector electrode.

FIG. 12A is another embodiment illustrating a connection of the hole injector/collector metal to the GaN material.

FIG. 12B is another embodiment illustrating a thinned region of the GaN material.

FIGS. 13A, 13B(1), 13B(2), 13C, 13D, 13E, 13F, 13G illustrate a process of fabricating a GaN device in accordance with embodiments herein.

### DETAILED DESCRIPTION OF THE EMBODIMENTS

In the following detailed description, reference is made to certain embodiments. This detailed description is merely intended to teach a person of skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings. It is to be understood that other embodiments may be employed and that various structural, logical, and electrical changes may be made.

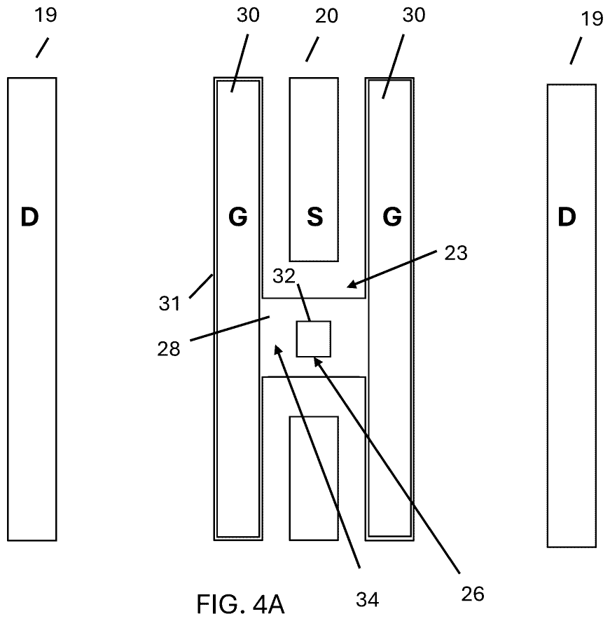

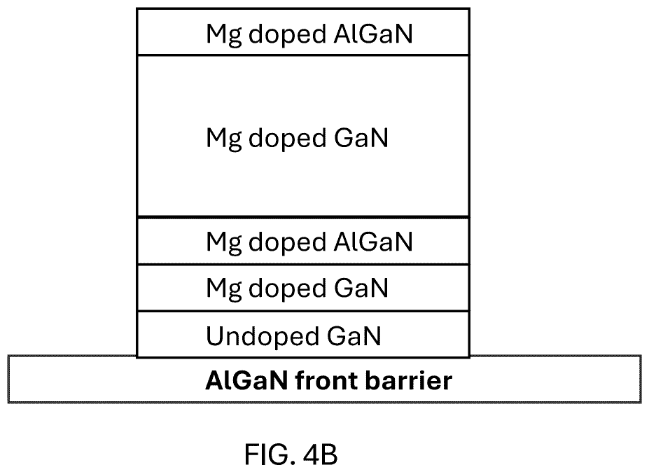

Referring to the drawings, FIGS. 4-13 show a novel Gallium Nitride (GaN) High Electron Mobility Transistor (HEMT) device 10 with multiple metal contacts to a single contiguous p-GaN layer. The invention encompasses various embodiments which introduce innovative mechanisms for threshold voltage (Vth) control through hole injection and removal. The device 10 is configured to apply a positive voltage bias to a GaN material to inject holes into the GaN material beneath the gate, and also to apply a negative voltage bias to the GaN material to remove holes from the GaN material beneath the gate. It will be understood that the device can be configured in different ways, and several non-limiting example embodiments are shown and described in the present disclosure, which includes the device shown and described in U.S. patent application Ser. No. 19/207,772, filed May 14, 2025, and U.S. Publ. No. 2024/0274681, filed Aug. 15, 2024, the entire contents of which are herein incorporated by reference. However, this invention is not limited to the specific topologies detailed in the embodiments. It broadly encompasses any GaN transistor architecture that applies a positive voltage bias to inject holes into the gate material, and a negative voltage bias to remove holes from the gate material, and one such embodiment includes a single hole injector/collector electrode or multiple hole injector/collector electrodes connected to a single contiguous GaN material that is contiguous with the gate material.

FIGS. 4-6F show a non-limiting example embodiment of a device 10 having two contacts or electrodes to the GaN layer. The first contact serves as the traditional gate metal, while the second contact 140, namely a hole injector/collector electrode, is positioned separately from the gate electrode metal. This secondary contact can function as either a hole injector and/or a hole remover, based on the applied bias. Hole injection into the GaN material beneath the gate metal reduces the Vth via two primary mechanisms. In a trap depopulation, injected holes depopulate traps, thereby shifting the Vth back towards pre-shift levels. In a hole accumulation, accumulated holes within the GaN material beneath the gate further decrease the Vth below the desired threshold. To restore the original Vth, a negative bias may be applied to the injector tab, effectively removing excess holes from the gate. This dual-action process results in a gate with depopulated traps and removed excess holes, thereby controlling the Vth relative to pre-shift levels.

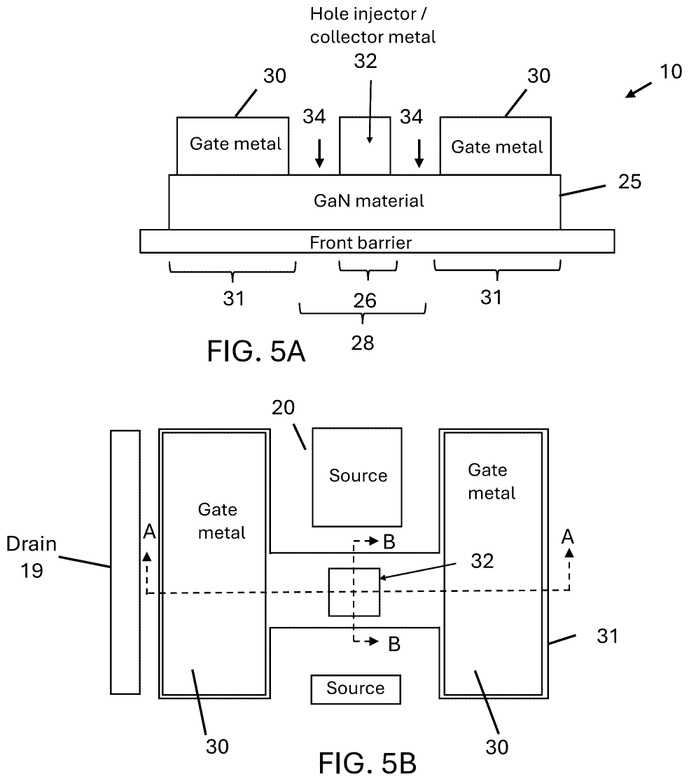

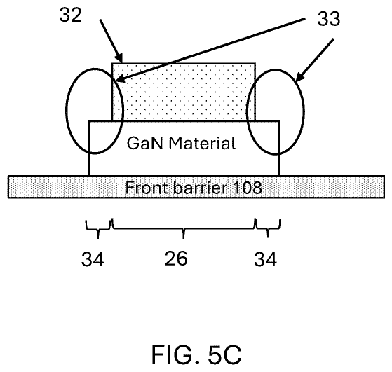

FIGS. 4A, 5B show top views of a first embodiment of the device of the present invention, FIG. 5A shows a cross-section view taken along line A-A of FIG. 5B, and FIG. 5C shows a cross-section view taken along line B-B of FIG. 5B. The device includes a source 20, gate 30, drain 19, a hole injector/collector assembly 23, and a III-V material layer, here a GaN material layer 25. The gate electrode metal 30 is laterally disposed between the ohmic contacts 19, 20 for the drain (D) and source (S), respectively. The gate metal 30 is formed over the GaN layer 25. As best seen in FIG. 5A, the hole injector/collector assembly 23 includes a hole injector/collector metal 32, which is also formed over the GaN layer 25 and is disposed between two portions of the gate metal 30.

As shown in FIGS. 4A, 5A, 5B, 5C, the GaN layer 25 is a continuous material formed over the front barrier layer, and includes a gate material section 31 under the gate metal 30 and a bridge section 28 between the gate metals 30. The bridge section 28 includes a hole injector/collector section 26 of the GaN material 25 which is directly below the hole injector/collector metal 32, and an uncovered section 34 section not directly below the hole injector/collector metal 32, but to the sides of the hole injector/collector metal 32. The bridge section 28 of the hole injector/collector GaN material 25 extends between the gates 30, and couples the hole injector/collector metal 32 to the gate material section 31.

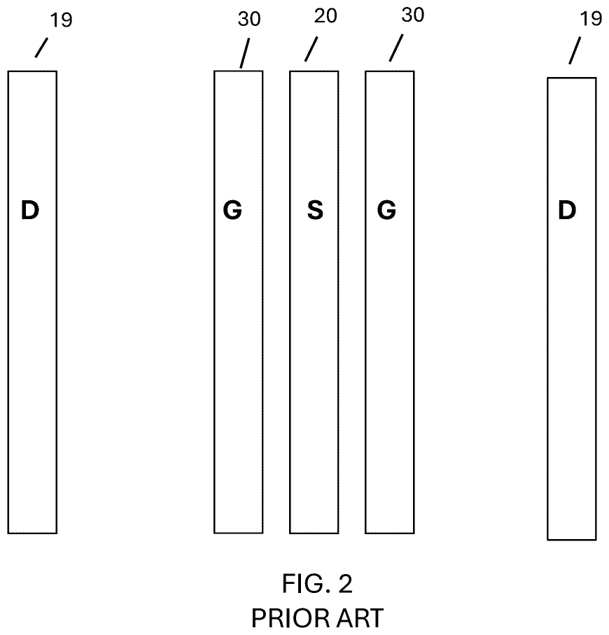

The gate metal 30 is disposed over the GaN gate material section 31, which is slightly larger than the gate metal 30, to form ledges 33 (FIG. 5C) of the GaN gate material. It is noted that gate ledges 33 need not be provided, such that the gate metal 30 can be the same size as the underlying GaN gate material; in such a case, the periphery of the GaN gate material section 31 is not visible in a top view, as shown for example in FIGS. 2, 6 and 7.

The hole injector/collector metal 32 is formed over at least a part of the GaN hole injector/collector section 28. The hole injector/collector eliminates holes that either pre-exist or accumulate in the GaN gate material under the gate metal 30. In the preferred embodiment of the present invention, the holes are removed from the gate region by any of several transport processes, including but not limited to: (1) recombination of the holes with electrons, thereby neutralizing the holes; (2) thermionic emission of holes over a Schottky metal contact; and (3) tunneling or injection of holes. As disclosed in more detail below, the electrons are sourced from a negative voltage generating circuit and injected into the GaN gate material of the enhancement mode GaN device.

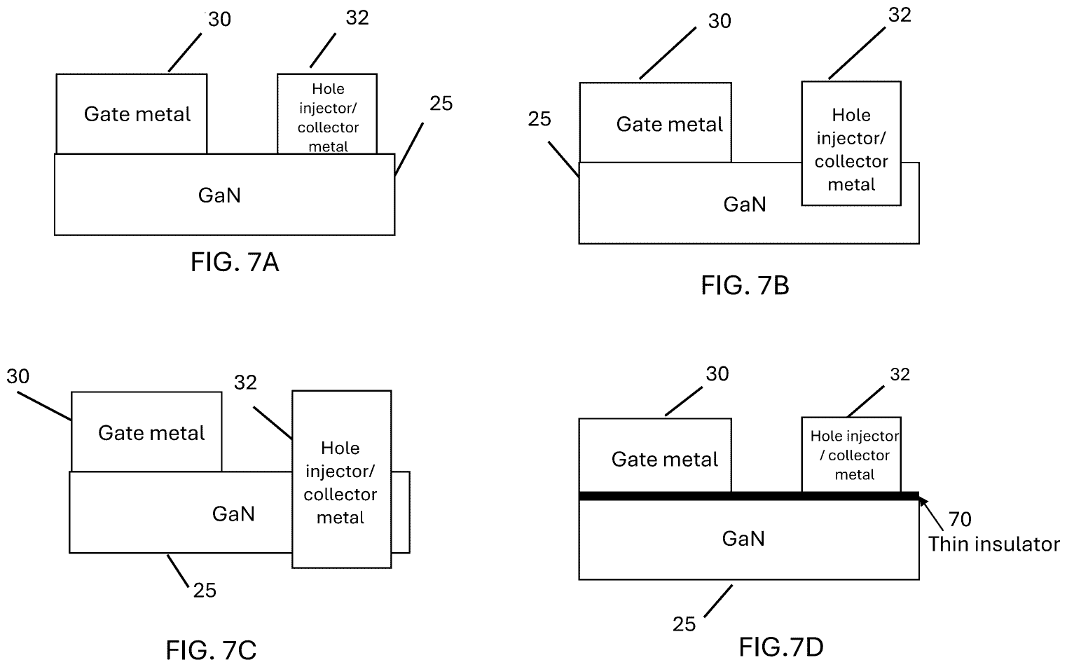

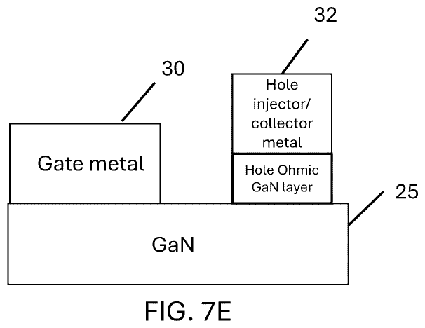

Thus, as best shown in the central portion of the top view of FIGS. 4A, 5A, 5C, the GaN material 25 is formed of three sections: (1) a gate GaN material section 31 in which the gate metal 30 is disposed over the GaN material 25 of the gate lines; (2) a hole injector/collector GaN material section 26 in which the hole injector/collector electrode 32 contacts the GaN material, as disclosed in further detail below with respect to FIGS. 7A-7E; and (3) an uncovered section 34, in which the GaN material has no metal over it, i.e., a distance exists between the gate metal 30 and the hole injector/collector metal 32.

In some embodiments, the GaN layer 25 is composed of AlₓGa_{y}In_{(1-x-y)}N of varying x and y values. The GaN material 25 is doped with a p-type dopant such as magnesium to create an enhancement mode device. The p-type GaN can be compensated, as disclosed in U.S. Pat. No. 8,350,294, the disclosure of which is incorporated herein by reference.

As shown in the example embodiment of FIG. 4B, the GaN layer 25 can have an undoped GaN bottom layer that is formed on the front barrier. A Mg doped layer of GaN can then be formed over the undoped GaN layer, followed by a Mg doped AlGaN layer, a Mg doped GaN layer, and a Mg doped AlGaN top layer. The thickness of the entire GaN material is from 20 nm to 120 nm.

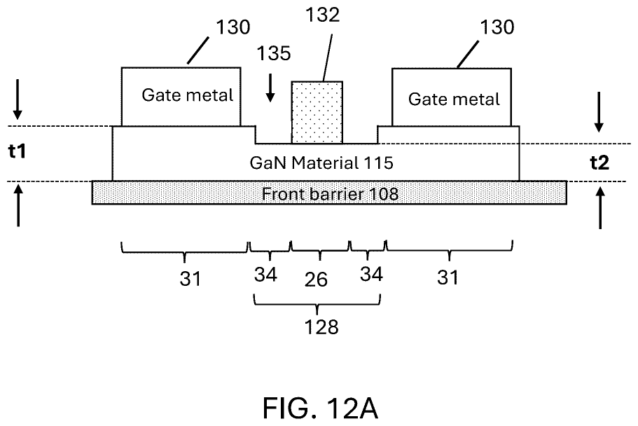

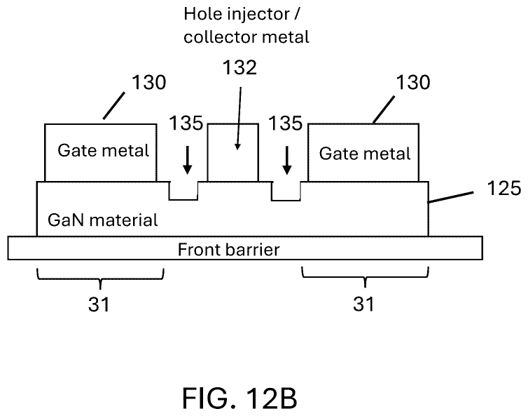

The GaN material below the hole injector/collector contact metal 32 (FIGS. 4-7), 132 (FIGS. 12A-12B) may be thinner than the GaN material of the gate lines 30, 130. Likewise, the hole injector/collector section 28, 128 of the GaN material 25 can either have the same thickness as the GaN material of the gate lines 30, 130, or can be thinner than the gate lines. FIGS. 12A and 12B illustrate the case where the GaN material is thinner, at least in part, in the gap between the gate contact metal and the hole injector/collector metal. In FIG. 12A, the entire bridge section 128 (including the hole injector/collector section 26 and the uncovered section 34) is thinner than the gate section 31; whereas in FIG. 12B, the uncovered section 135 is thinner, and the hole injector/collector section 34 is the same thickness as the gate section 31.

A cross-sectional view of the first embodiment of the present invention is shown in FIG. 5A. The gate metal 30 is preferably TiN. The hole injector/collector metal 32 may be formed of the same metal as the gate metal 30, or may be formed of a different metal. The contact of the hole injector/collector metal 32 to the GaN material 25 preferably has a lower barrier height than the gate metal contact to the GaN material 25, and serves as a preferential site to attract holes and, in the preferred embodiment, neutralize the holes with electrons.

FIG. 5C shows a cross-section view taken along line B-B of FIG. 5B. The GaN material 25 may be 20 nm to 120 nm thick. The gate metal 30, 130 and the hole injector/collector metal 32, 132 (FIGS. 5A, 5B) are spaced apart by a distance of about 0.1 μm to 50 μm. In the embodiment of FIGS. 5A-5C, the GaN material layer 25 has a uniform thickness. FIG. 5C illustrates self-aligned gate ledges 33 to space the hole injector/collector metal 32 from a side surface of the GaN uncovered material 34 to reduce gate leakage.

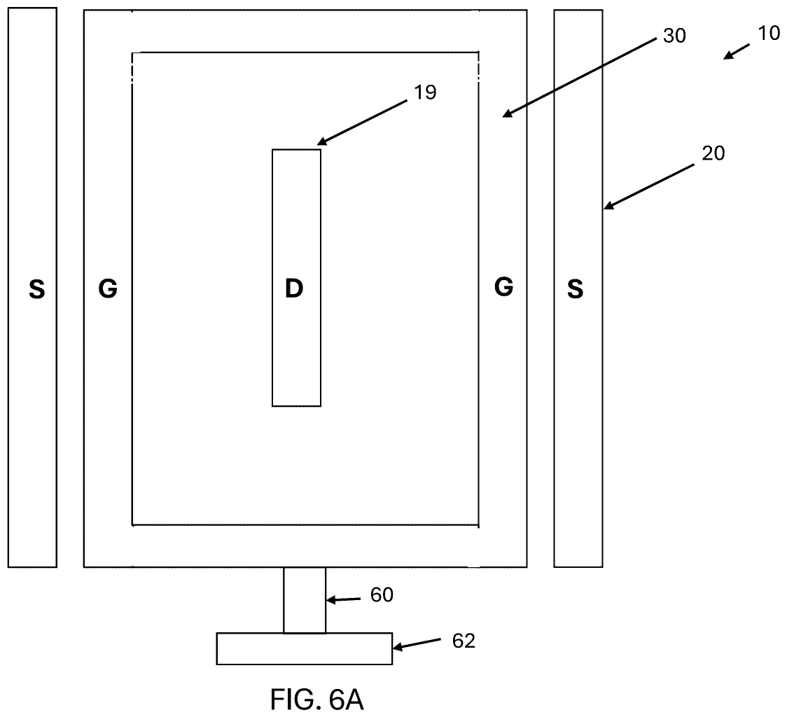

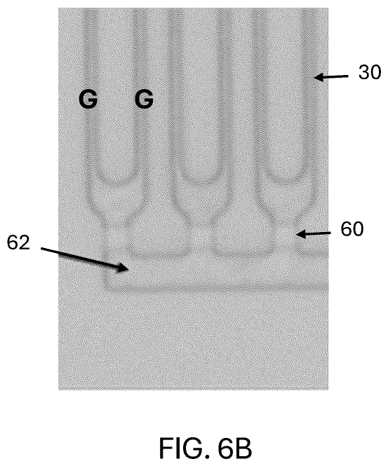

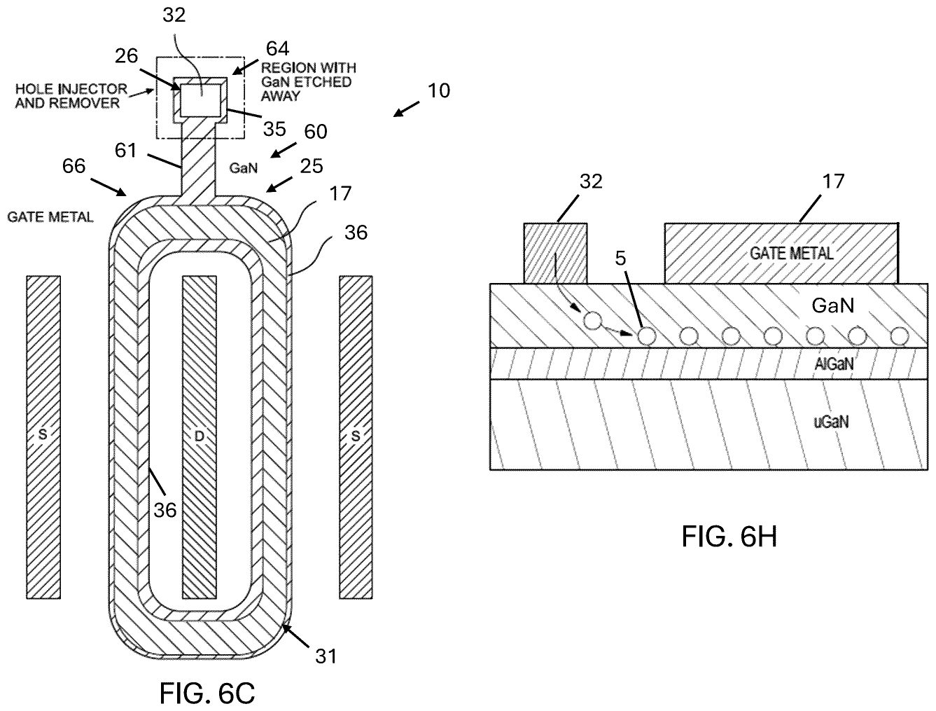

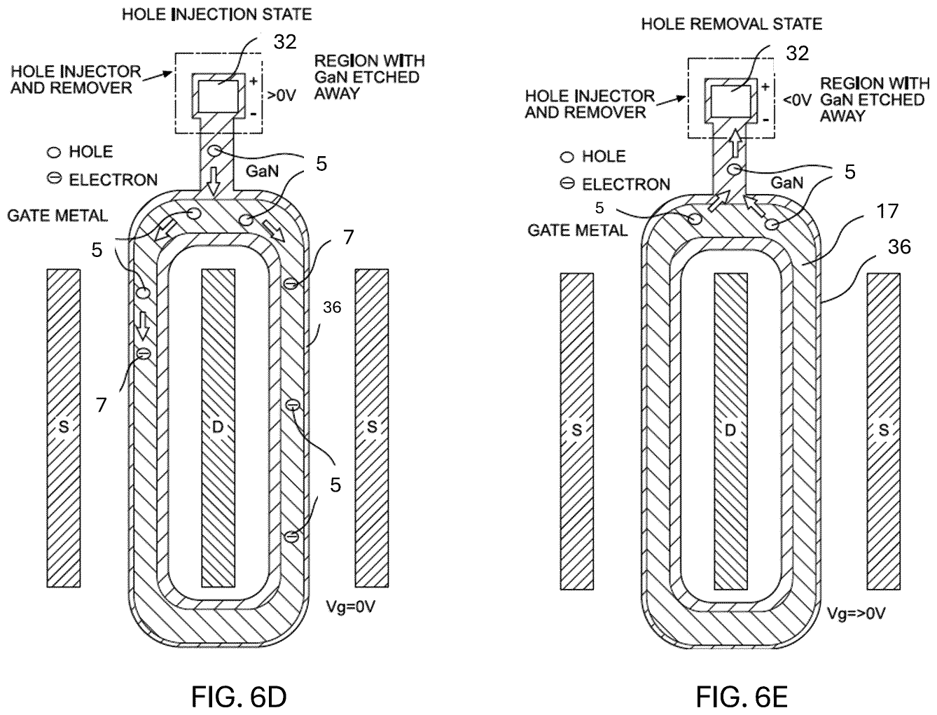

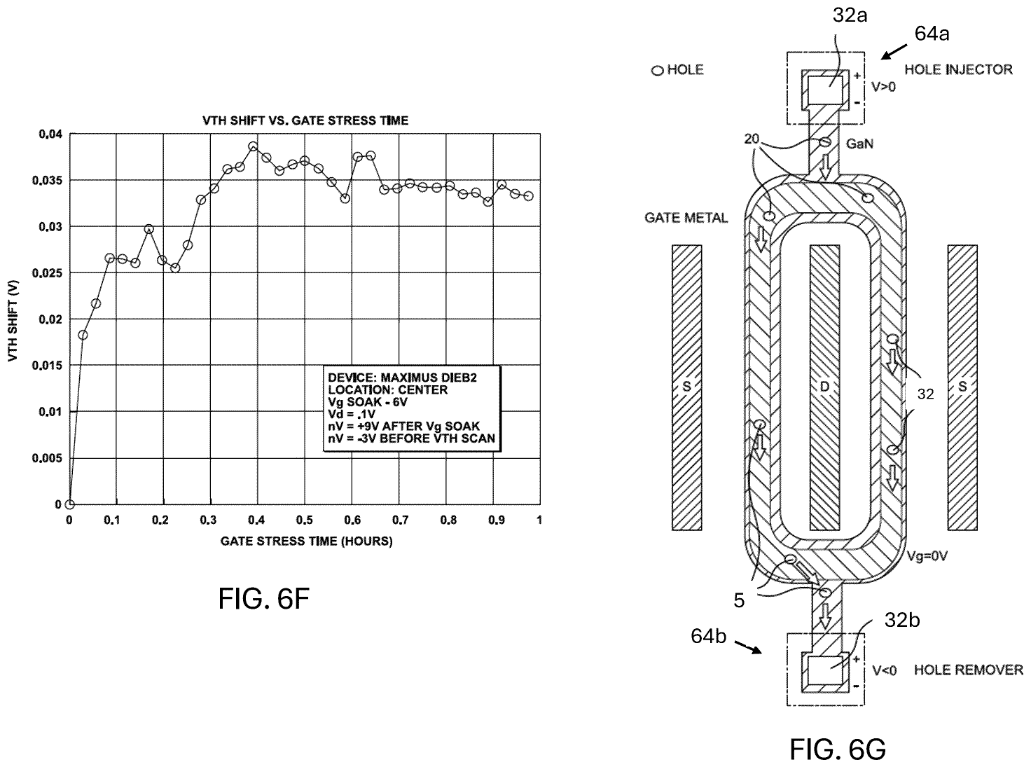

### Single Injector/Collector Electrode Racetrack (FIGS. 6A-6F)

In FIGS. 4 and 5, the hole injector/collector 23 is coupled at two opposite sides to respective gate metal contacts 30 by the GaN bridge 28, so that the GaN bridge and hole injector/collector metal 32 (e.g., an ohmic contact) are inside the gate racetrack GaN material.

FIGS. 6A, 6B show an alternative layout in which the hole injector/collector 23 is coupled at one side to a single annular gate 30. Here, the gate metal 30 forms a racetrack surrounding the drain contact 19. In this embodiment, the GaN bridge 60 extends from the GaN material below the gate metal 30, to the material beneath the hole injector/collector metal 62. Thus, the entire bridge 60 and the metal 62 making contact to the GaN material, are disposed outside of the gate racetrack. The bridge 60 couples the hole injector/collector GaN material and the hole injector/collector metal 62 to the gate GaN material. The gate 30 racetrack forms a continuous closed loop, such as in the form of a square, circle, or rectangle with curved corners, and the drain is positioned in the middle of the racetrack. In some embodiments, the hole injector/collector 62 can be connected with multiple racetracks or gates 30 by one or more segments of bridge material 60.

FIG. 6B is top view picture showing an example of gate contact metal 30 and hole injector/collector metal 62, and the GaN material bridge 60 between the two metals 30, 62. The GaN material forms a continuous network, and shows multiple racetrack gates 30 of FIG. 6A. As shown, the GaN material is only visible in the gap or bridge 60 between the gate metal 30 and the hole injector/collector metal 62. The GaN material extends under the gate metal 30, under the hole injector/collector metal 62, and forms the bridge 60.

FIG. 6C shows a top view of a GaN device 10 in accordance with the present invention having a single hole injector/collector electrode. The GaN device 10 includes a hole injector/collector metal contact 32 (e.g., an ohmic contact) for eliminating holes accumulating in the gate GaN material 31 under the gate metal 17. The GaN device 10 includes a gate section 66, bridge section 60 and a hole injector/collector section 64. The gate section 66 includes the gate metal 17, the gate GaN material 31 directly below the gate metal 17, and the uncovered gate GaN material 36 (as shown in the present embodiment, the GaN material is wider than the gate metal 17). As shown, the gate section 66 is a closed loop, and (in the example shown) has a racetrack or elongated-O shape or rectangular shape with rounded corners. A drain is in the center of the racetrack, and sources are on either sides of the racetrack, so that the elongated sides of the gate are between a source and a drain.

The hole injector/collector section 64 includes a hole injector/collector metal 32, a hole injector/collector GaN material section 26 directly below the hole injector/collector metal 32, and an uncovered hole injector/collector GaN material section 35 (the GaN material is larger than the hole injector/collector metal 32 and includes the uncovered section 35 which extends around the hole injector/collector metal 32, and the hole injector/collector GaN material section 26).

The bridge section 60 is formed completely of GaN material and extends between the hole injector/collector section 64 and the gate section 66. The bridge GaN material 60 is contiguous and couples with the uncovered hole injector/collector GaN material 35 (which is contiguous and couples with the hole injector/collector GaN material 26) and the uncovered gate GaN material 36 (which is contiguous and couples with the gate GaN material 31). The bridge section 60 electrically isolates the hole injector/collector electrode 32 from the gate electrode 17.

Thus, the GaN material layer 25 is a single contiguous layer that includes the gate GaN material section 31 (directly below the gate metal 17), the uncovered gate GaN material section 36 (to the sides of the gate GaN material 31), the hole injector/collector GaN material section 26, the uncovered hole injector/collector section 34, and the bridge GaN material 60.

### Hole Injector/Collector Operation (FIGS. 6D, 6E)

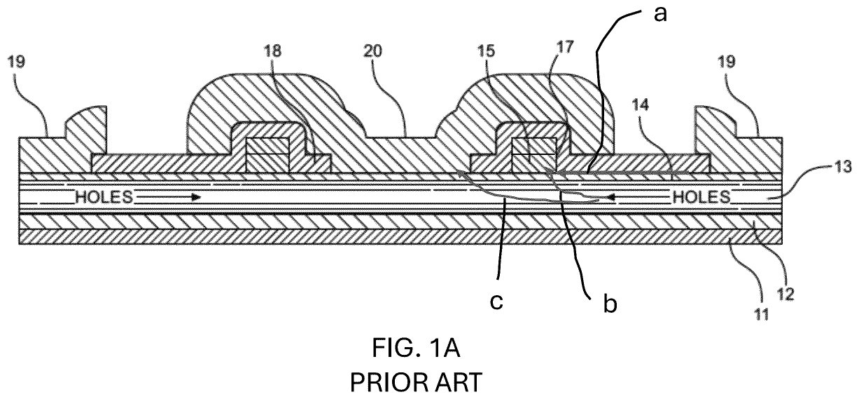

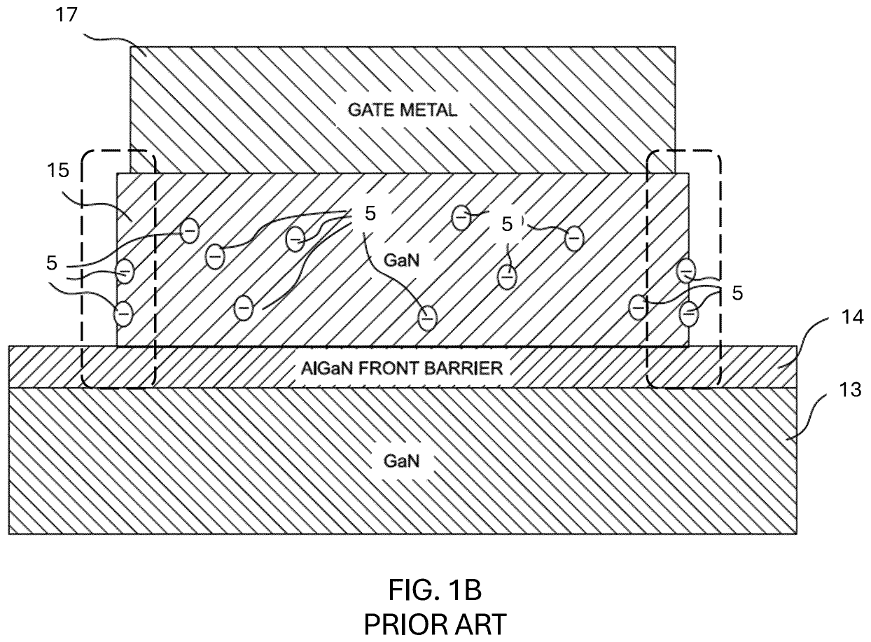

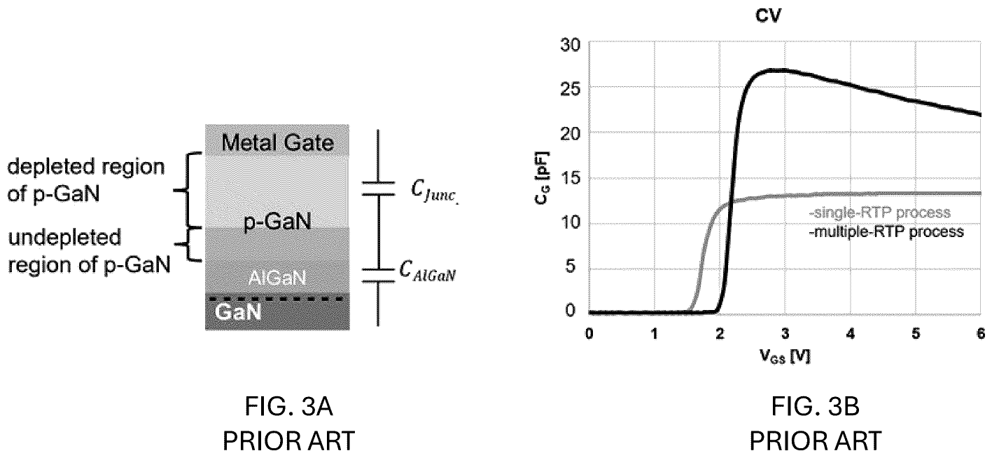

Referring to FIGS. 6D, 6E, 6H, the device 10 has two primary modes of operation, namely a hole injection operation (FIGS. 6D, 6H), and a hole collection operation (FIG. 6E). It is noted that these modes of operation are shown and described with respect to the racetrack embodiment of FIG. 6C. However, it is recognized that the modes of operation can be applied to the embodiments of FIGS. 1-6B, and to any suitable configuration in which holes can be injected and removed from GaN material. The invention is not limited to the specific topologies detailed in the embodiments shown and described in the present disclosure. It broadly encompasses any GaN transistor architecture employing two or more metal contacts and/or field-plates connected to a single contiguous GaN region.

Vth shifting may be induced by trapped electrons 7 in the gate GaN material 31 and/or the uncovered gate GaN material 36 (in those embodiments where the GaN material is larger than the gate metal 17). This can be counteracted by injecting holes 5 (FIG. 6D) into the gate GaN material 31 via the hole injector/collector electrode 32 to depopulate the trapped electrons 7.

In the hole injection mode (FIG. 6D), electrons 5 are sourced from a positive voltage generating circuit and injected into the GaN gate material 34 via the hole injector/collector metal contact 32 of the enhancement mode GaN device 10. As noted, the hole injector/remover contact 32 is connected to the main gate contact 17 via the contiguous region GaN material layer 25. The positive voltage or voltage bias is applied to the hole injector/collector electrode 32. The positive bias injects holes 5 into the hole injector/collector GaN material 26. The holes 5 travel through the uncovered hole injector/collector GaN material 35, across the bridge GaN material 60, to the uncovered GaN gate material 36, and to the gate GaN material 31. Thus, the holes distribute throughout the gate structure 66, including throughout the gate GaN material 31 directly below the gate metal 17 and the uncovered gate GaN material 36. These holes 5 neutralize trapped electrons 7 that may have accumulated within gate GaN material 31 and/or the uncovered gate GaN material 36. By neutralizing the trapped electrons 7, the charge state and voltage threshold (Vth) is lowered and the voltage threshold of the gate may be restored or altered. The positive analog voltage applied to the hole injecting contact 32 determines the amount of Vth reduction, with a higher bias causing more hole injection and greater reduction in Vth of the main FET.

Once holes 5 are injected in the injection mode (FIG. 6D), the electrons 7 or traps, will be depopulated. However, there may be an excessive number of holes 5 within the gate structure resulting in a lower Vth than desired. In the hole collection mode (FIG. 6E), any excess holes 5 that may accumulate as a result of the hole injection process may be subsequently removed by altering the voltage bias at the hole injector/collector electrode 32 so that instead of injecting holes, the holes are removed. The excess holes 5 may be removed by applying a negative bias on the hole injector/remover contact 32 to restore the Vth to a higher or previous value. The hole injector/remover contact 32 injects holes when it is biased positively relative to the source 20, and removes holes when it is biased negatively with respect to the source 20.

The hole injection mode and the hole collection mode can be operated as needed. For example, a digital and/or analog circuit device or processing device (e.g., a processor or controller) can be provided that determines the Vth level. If the circuit detects a high Vth (e.g., by comparing the detected Vth to a first maximum Vth threshold level), it can provide, or trigger a voltage source (e.g., by sending an injection control signal) to provide, a positive voltage bias to the hole injector/collector electrode 32 to reduce the Vth. If the circuit detects a low Vth (e.g., by comparing the detected Vth to a second minimum Vth threshold level, which is the same or different than the first threshold level), it can provide, or trigger a voltage source (e.g., by sending a collection control signal) to provide, a negative voltage bias to the hole injector/collector electrode 32 to reduce the Vth. Still further, the circuit can control the magnitude of the positive voltage, for example if the detected Vth is greater than a third Vth threshold, it can provide or trigger a larger positive bias to the hole injector/collector electrode 32 to further reduce the Vth.

Thus, the circuit can coordinate the voltage magnitude, hole injection, and hole collection, to provide a predetermined or desired Vth. For example, it may raise/lower the voltage magnitude during injection and/or collection and switch from injection to collection; or, it can increase the positive voltage bias for injection, and turn off or lower the negative voltage bias on collection. The circuit control can operate continuously, automatically, without manual intervention, and dynamically based on the detected Vth, and in real time, to tune the Vth. In other embodiments, the circuit can simply alternate between the hole injection mode and hole collection mode at regular predefined intervals. For example, it can operate the device 10 in the hole injection mode for a first predetermined period of time, then in a hole collection mode for a second predetermined period of time that is the same or different than the first predetermined period of time. Or, it can include a rest period between the hole injection mode and hole collection mode, during which no bias is provided to the hole injector/collector electrode. This kind of control loop can be implemented in several ways, e.g. as an analog controller inside the GaN IC, or an external digital controller. In one embodiment, the relative duty cycle of injection vs removal phases is varied.

FIG. 6F illustrates the Vth shift under dc 6V gate stress of a device 10. Intermittently, the threshold voltage is measured. Before each threshold voltage measurement, the Vth of the device 10 is reset. A total shift of approximately 35 mV was observed over an hour of 6V gate stress which is approximately 50× less Vth shifting than without the use of the reset mechanism.

### Multiple Hole Injector/Collector Electrodes (FIG. 6G)

FIG. 6G shows another non-limiting exemplary embodiment of the invention. Here, the device includes a first hole injector/collector section 64a and a second hole injector/collector section 64b separate from the first hole injector/collector 64. Thus, there are three contacts to the GaN layer 25, namely the gate metal 17, second hole injector/collector metal 32a, second hole injector/collector metal 32b, facilitating continuous hole injection and removal. A positive and/or negative voltage bias can be applied to each the first hole injector/collector metal 32a and/or the second hole injector/collector metal 32a. For example, a negative bias or positive bias can be sequentially applied to both contacts 32a, 32b. In addition, a positive bias can be applied to the first hole injector/collector metal 32a to continuously inject holes 5, while at the same time a negative bias can be applied to the second hole injector/collector metal 32b to continuously remove holes 5. This simultaneous injection and removal process ensures trap depopulation without unnecessary hole accumulation within the gate GaN material and uncovered gate GaN material. In some embodiments, the voltage biases can then be reversed, so that the first hole injector/collector metal 32a receives a negative bias and the second hole injector/collector metal 32b receives a positive bias.

Thus, the Vth is reset by injecting and removing holes from the main gate. Electron traps are depopulated by a continuous stream of injected holes that move from the first hole injector/collector metal 32a to the second hole injector/collector metal 32b through the entirety of the gate GaN material 31 and/or uncovered gate GaN material 36. This allows for the injector/remover terminals 32 to be de biased, simplifying the control circuit for the Vth reset. The main gate and essential function of the FET (i.e., Source 20, Drain 19, Gate 17 terminals) are not affected by the ancillary terminals. Of course, the device 10 of FIG. 6G can have similar operation as discussed with respect to FIGS. 1-6F above. In some of the embodiments discussed, the hole injector/collector electrode 32 is only used as an injector, and in some embodiments the hole injector/collector electrode 32 is only used as a collector, and in some embodiments the hole injector/collector electrode 32 is used as both an injector and collector.

It is further noted that hole injection and collection has been described and shown with respect to FIGS. 6C-6G. However, it can be used with any of the embodiments of FIGS. 4-6B, or other suitable devices.

### Hole Injector/Collector Metal 30 (FIG. 7)

With respect to the embodiments of FIGS. 1-6G, various possible connections of the hole injector/collector metal 32 to the GaN material 25 are shown FIGS. 7A-7E. FIG. 7A shows an embodiment in which the hole injector/collector metal 32 is in direct contact only with the top surface of the GaN material 25. As shown in the cross-section view of FIG. 7B, in some embodiments the hole injector/collector metal extends into a recess in the GaN material 25. As shown in the cross-section view of FIG. 7C, in some embodiments the hole injector/collector metal 32 extends completely through the GaN material 25. FIG. 7D shows an embodiment in which a thin insulator 70, such as Si₃N₄, AlN or Al₂O₃, is disposed between the metal contacts 30, 32 and the GaN material layer 25. Thus, the insulator layer has a bottom surface that is formed over the top surface of the GaN layer 25, and the gate metal 30 and hole injector/collector metal 32 each have a bottom surface that is formed over the top surface of the insulator. The thickness of the insulator 70 is from 0.1 nm to 3 nm. In this embodiment, the holes, which are mobile, tunnel from GaN material 25 through the insulator 70 to the hole injector/collector metal 32. A fifth embodiment, not shown, is a combination of the embodiments of FIGS. 7B and 7D, in which the hole injector/collector metal extends through insulator 70 into a recess in the GaN material 25.

FIG. 7E shows a hole ohmic GaN layer (which can be GaN, pGaN, or a heavily doped pGaN, p++ GaN) disposed over the GaN material layer 25, and the hole injector/collector metal 32 disposed over the hole ohmic GaN layer. Thus, the hole ohmic GaN layer can be above the gate GaN layer and under the hole injector/collector contact. The hole ohmic GaN layer improves the creation of a truly ohmic connection between metal GaN layer. It can be challenging to make an ohmic contact for holes into GaN, so this layer can be very heavily Mg doped GaN to create a local tunnel junction for forming an ohmic connection.

As previously noted, FIGS. 12A, 12B illustrate the case where the GaN material is thinner, at least in part, in the gap between the gate contact metal and the hole injector/collector metal, which can also be applied to the embodiments of FIG. 6. Referring to FIG. 12A, an embodiment is shown where the GaN material 115 is thinner in the bridge section 128, and the hole injector/collector metal 132 is positioned in a recessed portion 135 of the GaN material 115. The thickness t1 may be in a range from 20 nm to 120 nm, and the thickness t2 may be the same as or less than thickness t1.

FIG. 12B shows another embodiment. A channel or groove 135 is formed in the section 34 between the gate metal 30 and the hole injector/collector metal 32. Thus, the GaN material 125 is thinner in the region between the gate metal 130 and the hole injector/collector metal 132. The thinned regions of FIGS. 12A, 12B can be provided, for example, when etching the TiN.

The hole injector/collector metal 32, 132 is connected to a negative voltage. The negative voltage may be provided externally through an I/O terminal, or more preferably internally, through an integrated GaN circuit that generates a negative voltage. The negative voltage may also be provided by a silicon IC co-packaged with the GaN device, or can be part of an integrated voltage generator using a GaN IC. When the negative voltage is applied to the hole injector/collector electrode 32, 62, holes in the GaN gate material are removed.

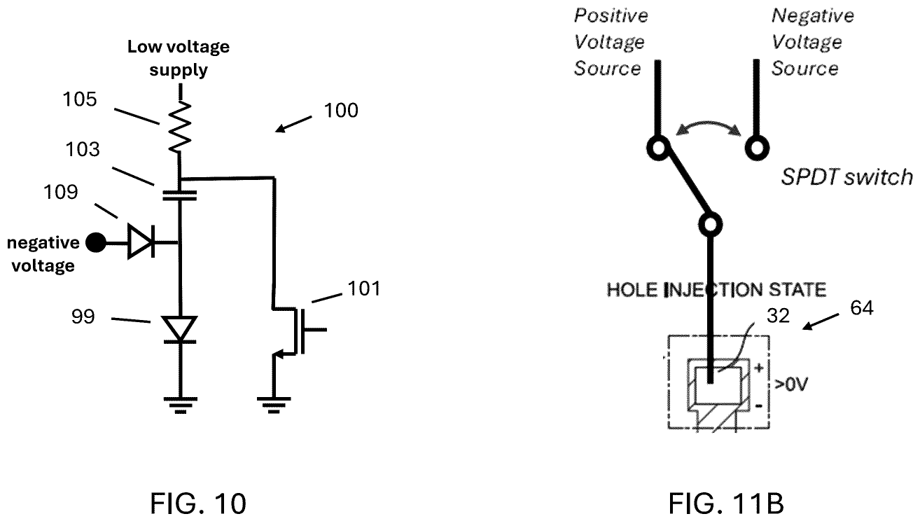

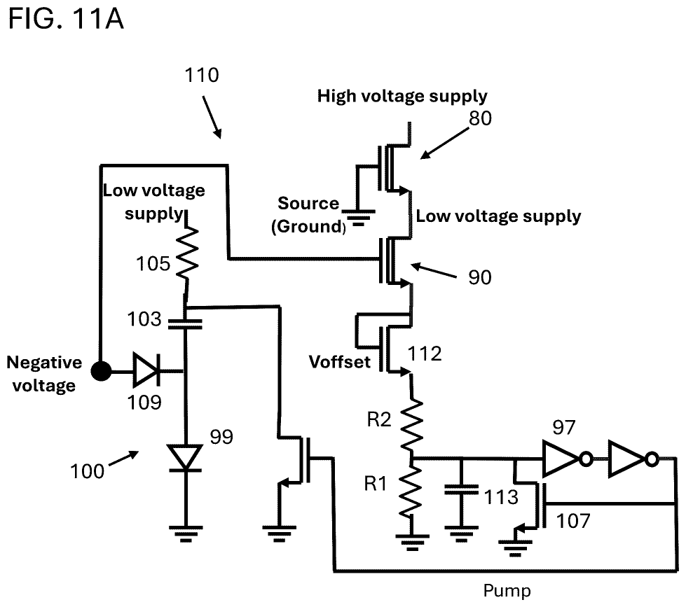

A preferred embodiment of an internal negative voltage generating circuit is shown in FIG. 11A. The circuit is implemented entirely in GaN so that it can be integrated with the GaN transistor, and uses a charge pump (FIG. 10) to generate the negative voltage. The circuit generates a negative voltage in the range of −2V to −14V with an extremely low current consumption of less than 10 μA.

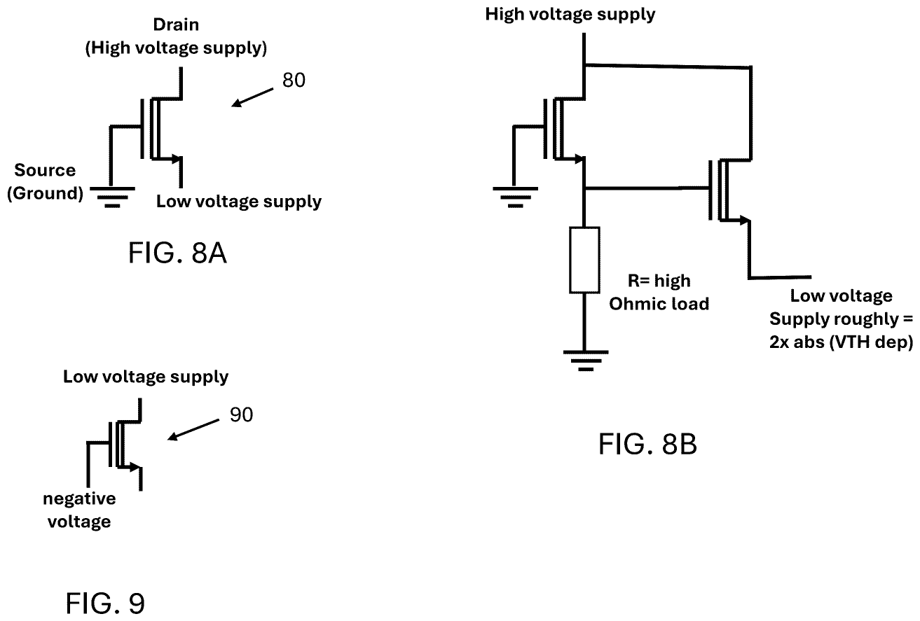

The internal voltage generating circuit uses a depletion mode GaN FET 80 as a linear supply. As shown in FIG. 8A, an enhancement mode GaN FET is modified to a depletion mode GaN FET. By connecting the gate to ground and applying a voltage greater than the absolute value of the threshold voltage Vth on the drain of GaN FET 80, the source of GaN FET 80 will generate a supply voltage equal to approximately the absolute value of the threshold voltage of GaN FET 80, which is 14V for our particular depletion mode device design. This Vth can typically range from 1 to 20V. Thus, the source will generate a supply voltage of approximately −14V for our design. The low voltage supply is roughly the absolute value of the depletion FET threshold. In some cases, this supply can be too low (example if the Vth dep is closer to zero than −5V). If that case, the voltage generation circuit of FIG. 8B can be used to duplicate the low voltage supply (or even triplicate if needed).

In order to reduce the total current that the circuit can sink from the supply to 10 μA, circuitry is included to sense the negative voltage and activate the charge pump only when it is needed. As shown in FIG. 9, the sensor circuitry includes a depletion mode GaN FET 90 with its gate connected to the negative output of the voltage generating circuit of FIG. 9 (see FIG. 11A). GaN FET 90 of FIG. 9 acts as an up-level shifter. The voltage at the source of GaN FET 90 is equal to negative output of the voltage generating circuit plus the absolute value of the threshold voltage (approximately 14V). As explained below with respect to the complete circuit of FIG. 11A, if the negative output of the voltage generating circuit plus 14V minus Voffset multiplied by the factor R1/(R1+R2) is greater than the threshold voltage of the inverter, then the charge pump (FIG. 10) is activated.

The operation of the charge pump circuit 100, shown in FIG. 10, is as follows. In steady state, the charge pump enhancement mode GaN FET 101 is OFF, the upper plate of the charge pump capacitor 103 is charged to the low voltage (LV) supply by resistor 105, and the lower plate of charge pump capacitor 100 is close to ground due to diode 99. The charge pump is activated by turning on GaN FET 101. Once GaN FET 101 is conducting, the upper plate of capacitor 103 is pulled down to ground and the lower plate of capacitor 103 is pulled below ground. At this point, diode 106 is turned on and the negative output of the voltage generating circuit is also pulled below ground. Diodes 99 and 109 in the circuit of FIG. 10 can be pn junction diodes, Schottky diodes or diode connected GaN FETs.

The operation of the sensing circuit is now described with reference to FIG. 11A, which shows the complete negative voltage generating circuit 110. Depletion mode FET 80 generates the low voltage supply for the circuit. Depletion mode FET 90 senses the negative voltage generated by charge pump circuit 100. The source of FET 90 is approximately 14V higher compared to the gate. The source voltage can be lowered by a voltage offset (Voffset) via gate-to-drain connected FET 112 to reduce current consumption and charges a capacitor 113 through a voltage divider formed of resistors R1 and R2.

Once the voltage on capacitor 113

$$( negative voltage + \vert {V}_{Th}^{Dep} \vert - V offset ) \frac{R 1}{R 1 + R 2}$$

reaches the threshold of inverter 97, the charge pump 100 is activated. The Pump signal triggers the charge pump circuit 100. The Pump signal also resets capacitor 113 through FET 107.

The circuit of FIG. 11A can be used to generate a negative voltage when only a positive external voltage supply is available. However, this negative voltage could be supplied in many alternative ways, including it could be supplied external to the GaN IC. Assuming two voltage supplies: (1) a negative supply with respect to the source electrode in FIG. 6C; and (2) a positive supply with respect to source electrode, these two voltages can be alternately applied to the hole injector/remover contact 32 (e.g., FIG. 6C) using a conventional single pole-double throw (SPDT) switch as depicted in FIG. 11B. Holes are injected during the positive phase, and are removed during the negative phase. Depending on the frequency of switching, and the relative duty cycle of positive vs negative phases, a certain steady state hole population can be achieved within the GaN material under the gate metal (FIG. 6C), thereby establishing a certain Vth of the transistor.

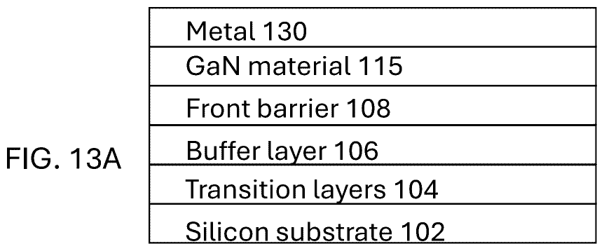

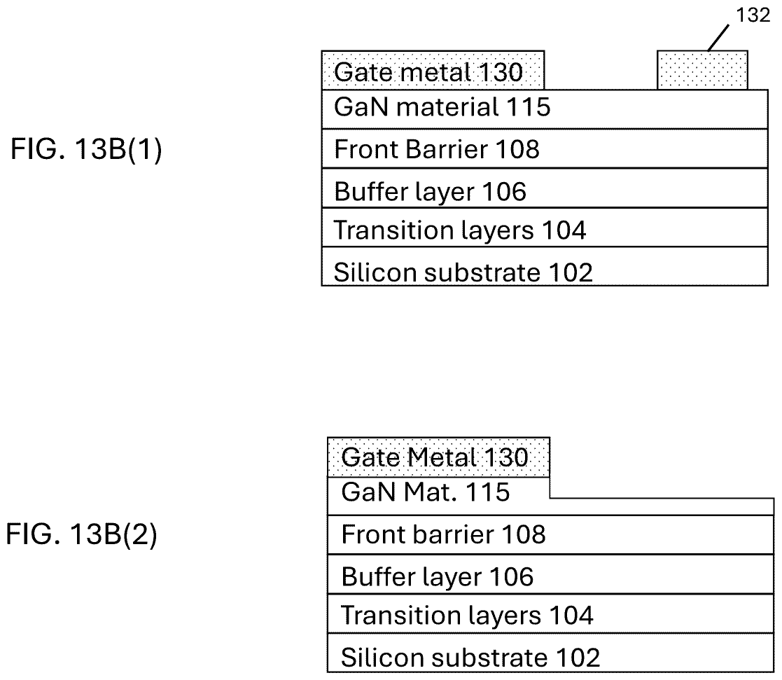

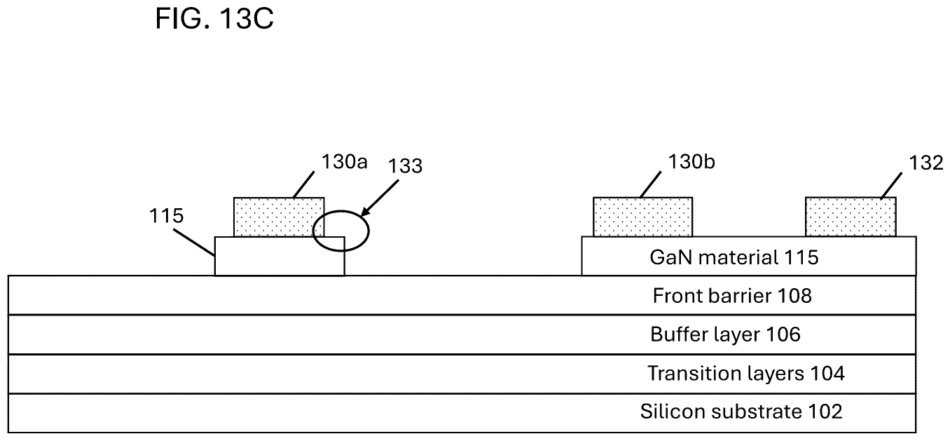

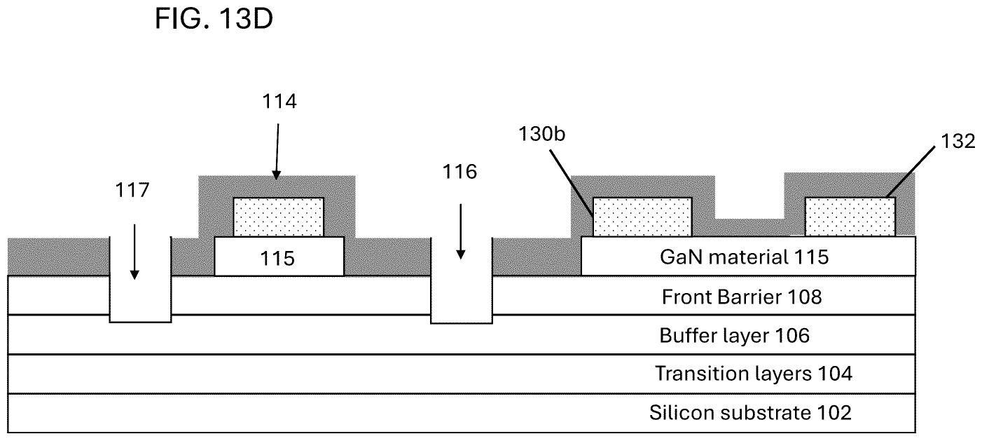

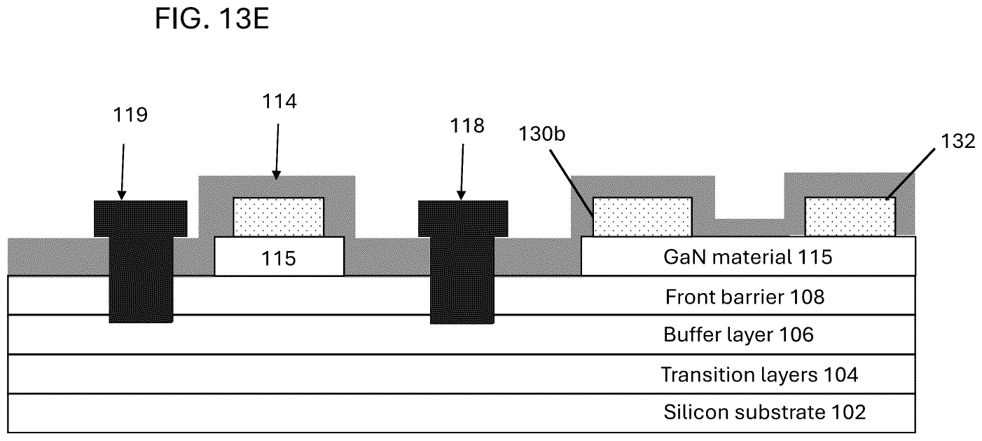

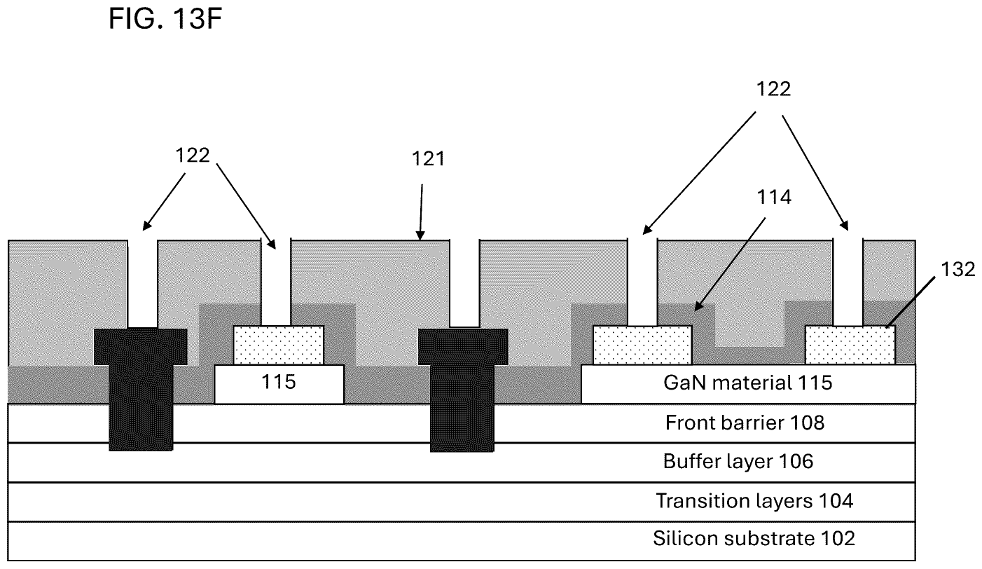

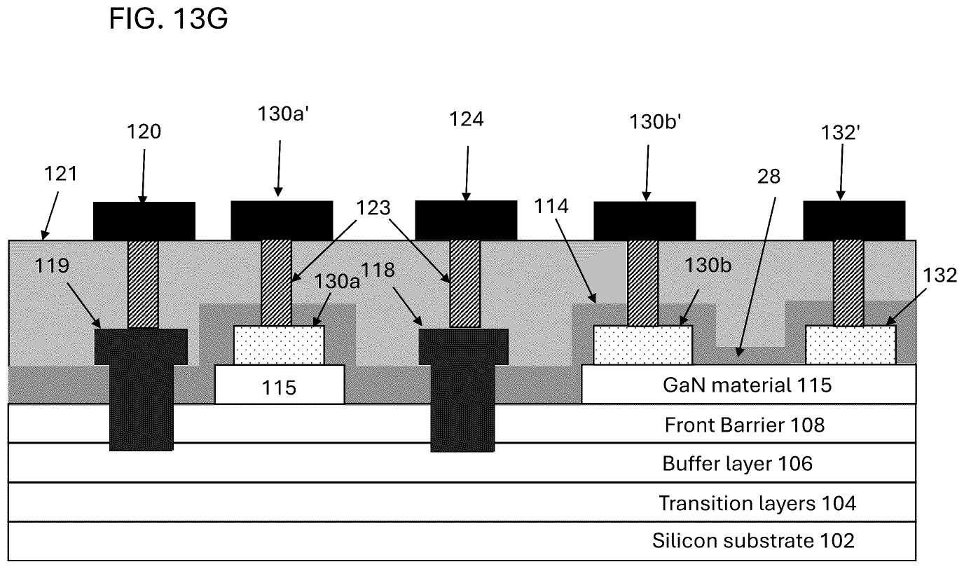

### Fabrication Process (FIGS. 13A-13G)

FIGS. 13A-13G illustrate a process of fabricating an enhancement mode GaN device in accordance with embodiments herein. Similar to conventional formation of enhancement-mode GaN transistors, the description of the process begins from a structure (e.g., an epitaxial structure) that includes a silicon substrate 102, one or more transition layers 104 formed on the top surface of the substrate 102, a buffer layer 106 formed on the top surface of the transition layers 104, and an AlGaN front barrier layer 108 formed on the top surface of the buffer layer 106, for example, as disclosed in U.S. Pat. Nos. 8,890,168 and 10,622,455, the entire disclosures of which are incorporated herein by reference.

In accordance with embodiments herein, as shown in FIG. 13A, the front barrier 108 has a barrier top surface. A GaN material layer 115 is disposed (e.g., epitaxially disposed) on the barrier top surface of the barrier layer 108. The GaN material layer 115 has a GaN material top surface, and a deposition of a metal layer 130, such as titanium nitride (TiN) layer, is made on the GaN material top surface. The GaN material layer 115 may be 20 nm to 120 nm thick. The metal layer 130 may include TiN, Ti, Au, Cu, or other metals and metal combinations, and has a gate metal top surface.

From this structure, different options of etching the metal layer 130 are demonstrated in FIGS. 13B(1) and 13B(2) in accordance with embodiments herein. In FIG. 13B(1), the metal layer 130 is masked using a first mask and a portion of the metal layer 130 is etched to expose the GaN material layer 115 and form the gate metal contact 130 and the hole injector/collector contact 132 (or multiple hole injector/collector contacts 132, such as for the embodiment of FIG. 6G), while maintaining the GaN material layer 115. The hole injector/collector contact 132 may be formed by the metal layer 130 or a second metal deposited on the GaN material layer 115. For example, the etched portion of the metal layer 130 may form a first portion of the metal layer 130 that forms the gate electrode 130b and a second portion of the metal layer 130 that forms the hole injector/collector electrode 132 (FIG. 13C). Alternatively, the hole injector/collector contact 132 may be formed by depositing a second metal on the GaN material layer 115 exposed by etching the portion of the metal layer 130. The second metal may be a different material than that of the gate metal contact 130b. The lateral spacing between the gate metal contact 130b and the hole injector/collector electrode 132 may be 0.1 um to 50 um.

Optionally, in FIG. 13B(2), a portion of the metal layer 130 and the GaN material layer 115 is masked and etched in the formation of the hole injector/collector contact. The etching of the portion of the GaN material 115 may be performed using the same etching process as the metal 130 or the portion of the GaN material 115 may be etched separately after the metal 130. The etching process removes the entire part of the etched gate metal layer 130 and a portion of the etched GaN layer 115, so that the remaining GaN layer 115 is thinner than the surrounding GaN material layer 115, as further shown in FIG. 12. Further, FIG. 13B(2) illustrates the avenue for using alternative metals and/or other configurations for the hole collection. For example, a different metal from the gate metal may be disposed to form the hole collection contact(s) 132, and/or further metal/Schottky junctions may be incorporated to integrate control of the negative voltage supply for efficient hole collection.

Thus, in both of FIGS. 13(B)(1) and 13(B)(2), the GaN layer 115 is exposed, so that the gate metal 130 and hole injector/collector metal(s) 132 are electrically and separately structurally connected to the GaN material layer 115. Proceeding with the example in FIG. 13B(1) and referring to FIG. 13C, a portion of the metal layer 130 and the GaN material layer 115 is etched using a second mask to form the gate contacts 130a, 130b of the device. In some embodiments, the metal layer 130 may be further be partially wet-etched to form a self-aligned gate ledge 133 of the GaN material 115 from the gate metal 130a, as shown in FIG. 13C. Etching the at least one self-aligned gate ledge may be performed with a wet etch and may be performed by a process as described in U.S. Pat. No. 9,748,347, the entire disclosure of which is incorporated herein by reference.

In FIG. 13D, a first dielectric layer 114 is deposited over the device, including the portions of the gate metal layer 130, the hole injector/collector metal(s) 132, the GaN material layer 115, and the barrier layer 108. The dielectric layer 114 may be deposited using Low-Pressure Chemical Vapor Deposition (LPCVD). The dielectric 114 is preferably silicon nitride (Si₃N₄) with a thickness of ˜80 nm. The thickness of the dielectric layer 114 may vary from 20 nm to 200 nm in accordance with embodiments. The deposition of the dielectric 114 may further include annealing. For example, the ˜80 nm Si₃N₄ dielectric may be annealed at 850° C. The annealing temperature may vary from 750° C. to 950° C. for the Si₃N₄ dielectric.

After the deposition of the dielectric layer 114, a mask may be applied and portions of the dielectric layer 114 and the barrier layer 108 are etched to form a via 116 for the drain contact and a via 117 for the source contact to, into or through the front barrier 108 to or into the buffer layer 106.

In FIG. 13E, an ohmic metal is deposited into the vias 116 and 117 to form the drain first contact 118 and a first source contact 119, respectively, using a mask, further etching, and Rapid Thermal Annealing (RTA) at 550° C. The RTA temperature may be from 500° C. to 900° C. in accordance with embodiments.

In FIG. 13F, an Inter-Metal Dielectric (IMD) layer 121 is deposited over the device, namely over the top surfaces of the dielectric layer 114, drain contact 118, and source contact 119, as well as any exposed GaN material 115. The dielectric of the IMD 121 may be silicon dioxide (SiO₂). Following the IMD 121 deposition, the device is planarized to have a flat top surface. Contact vias 122 are etched through the IMD layer 121 to the drain contact 118 and the source contact 119 to form the source electrode 120, the drain electrode 124, the gate electrodes 130a, 130b and a hole injector/collector electrode(s) 132.

In FIG. 13G, a tungsten (W) plug 123 is disposed in each of the contact vias 122 from FIG. 13F. Then, routing metal is disposed on each of the W plugs 123 to form connections to the source electrode 120, the gate electrodes 130a and 130b, the drain electrode 124, and the hole injector/collector electrode(s) 132 of the device. The contact vias 122 couple the source electrode 120 to the source contact 119, the gate contacts 130a′, 130b′ to the gate metals 130a, 130b, the drain electrode 124 to the drain contact 118, and the hole injector/collector contact(s) 132′ to the hole injector/collector metal(s) 132, respectively.

Unless otherwise noted, and without limiting the claims, it should be understood that the various elements and layers are entirely directly disposed on or formed on and in direct contact with one another. For example, as shown in FIG. 5A, the gate metal 30 and hole injector/collector metal 32 are directly disposed on or formed on and in direct contact with the GaN material layer 25, which is directly disposed on and in direct contact with the front barrier layer, which is directly disposed on and in direct contact with the buffer layer 106 (FIG. 13A), which is directly disposed on or formed on and in direct contact with the transition layers 104, which is directly disposed on or formed on and in direct contact with the substrate 102. Of course, other suitable embodiment can be provided, for example the elements and layers need not be entirely directly disposed on and in direct contact with one another, but can be partially directly disposed on and in direct contact with, or one or more elements or layers can be positioned therebetween, such as for example an insulator 70 (FIG. 7D) or other suitable materials. In addition, disposed on or formed on is intended to include that the elements can be in contact with the top surface of a layer, or partially or fully embedded within a layer. For example, the gate metal 30 and/or the hole injector collector metal can be to the top surface of the GaN layer, or partially or fully embedded within the GaN layer.

As shown in the drawings and as described above, the present invention advantageously includes a hole injector/collector which removes holes in the GaN gate material. As such, the GaN transistor of the present invention has lower gate leakage and a lower threshold voltage (Vth) shift. As further illustrated, the bottom surface of the hole injector/collector metal 32 and the bottom surface of the gate metal 30 are each directly connected to the top surface of the GaN layer 25. And the GaN layer 25 is a single continuous layer. The source electrode 20, drain electrode 19, gate electrode 30, and hole injector/collector electrode 32 are separate from each other. Accordingly, a negative voltage (with respect to the source) applied to the hole injector/collector 32 removes holes from the GaN gate material section 31.

In further accordance with the present invention, the contact can be configured to both inject or remove holes from the main gate. The gate material is a Group III-V material and can be, but is not limited to, p-type doped GaN, p-type doped AlGaN, compensated GaN or AlGaN, intrinsic GaN or AlGaN. Threshold shifting is induced by electron trapping within the gate GaN material, as shown by dots 7. This can be counteracted by injecting holes 5 into the gate GaN material to depopulate these traps. When holes 5 are injected, they travel and distribute throughout the main gate material. The injected holes 5 neutralize trapped electrons 7 that may have accumulated within the main gate material. By neutralizing the trapped electrons, the charge state and threshold voltage of the gate is restored. The gate material is a carrier material that carries a charge and can transfer a hole or electron.

Any excess holes 5 that may accumulate as a result of the hole injection process can be subsequently removed by altering the bias of the hole injector/collector contact so that instead of injecting holes, it removes them. The hole injector/remover is designed such that it injects holes when it is biased positively relative to source, and removes holes when biased negatively with respect to the source. Thus, hole injection is conducted by applying a positive bias on the hole injector/remover terminal. Once holes are injected the traps will be depopulated. However, there will be an excessive number of holes within the gate resulting in a lower threshold than desired. To recover the original threshold of the part, the excess holes are removed by applying a negative bias on the hole injector/remover terminal and the threshold is now reset to the original value.

The above description and drawings are only to be considered illustrative of specific embodiments, which achieve the features and advantages described herein. Accordingly, the embodiments of the invention are not considered as being limited by the foregoing description and drawings.

More generally, even though the present disclosure and exemplary embodiments are described above with reference to the examples according to the accompanying drawings, it is to be understood that they are not restricted thereto. Rather, it is apparent to those skilled in the art that the disclosed embodiments can be modified in many ways without departing from the scope of the disclosure herein. Moreover, the terms and descriptions used herein are set forth by way of illustration only and are not meant as limitations. Those skilled in the art will recognize that many variations are possible within the spirit and scope of the disclosure as defined in the following claims, and their equivalents, in which all terms are to be understood in their broadest possible sense unless otherwise indicated.

1. A gallium nitride (GaN) transistor having a voltage threshold at which the transistor turns ON, said enhancement mode transistor comprising:
a source electrode and a drain electrode;
a gate structure having a gate metal disposed on a GaN material; and
a first hole injector/collector electrode disposed on the GaN material and configured to adjust the voltage threshold by altering a number of holes or electrons in the GaN material.

2. The transistor of claim 1, wherein when a positive voltage bias is applied to said first hole injector/collector electrode, holes are injected into the GaN material to lower the voltage threshold.

3. The transistor of claim 2, wherein when a negative voltage bias is applied to said first hole injector/collector electrode, holes are removed from the GaN material and raise the voltage threshold.

4. The transistor of claim 3, further comprising a voltage source to supply the positive voltage and the negative voltage, wherein said voltage source comprises a silicon IC co-packaged with the GaN transistor, or an integrated voltage generator using GaN IC.

5. The transistor of claim 3, further comprising a voltage source to supply the positive voltage and the negative voltage, wherein the voltage source comprises an external device that delivers voltage through an input/output terminal.

6. The transistor of claim 1, wherein said GaN material serves as both GaN gate material under the gate electrode, GaN hole injector/collector material under the first hole injector/collector electrode, and as a connection from the GaN gate material to the first hole collector electrode.

7. The transistor of claim 1, further comprising:
a second hole injector/collector electrode disposed on the GaN material and configured to adjust the voltage threshold in coordination with said first hole injector/collector electrode by altering a number of holes or electrons in the GaN material.

8. The transistor of claim 7, wherein said first hole injector/collector electrode is configured to insert holes into the GaN material to lower the voltage threshold, and said second hole injector/collector electrode is configured to remove holes from the GaN material to increase the voltage threshold.

9. The transistor of claim 8, further comprising a voltage source configured to provide a positive voltage bias to said first hole injector/collector electrode to insert holes into the GaN material and lower the voltage threshold, and provide a negative voltage bias to said second hole injector/collector contact to remove holes from the GaN material and raise the voltage threshold.

10. The transistor of claim 9, wherein the positive voltage bias is provided simultaneously with the negative voltage bias.

11. The transistor of claim 1, wherein the GaN material comprises an AlₓGa_{y}In_{(1-x-y)}N material.

12. The transistor of claim 11, wherein at least a portion of the AlₓGa_{y}In_{(1-x-y)}N material comprises a p-type dopant.

13. The transistor of claim 1, wherein said gate metal is directly disposed on and in contact with the GaN material, and said first hole injector/collector electrode directly disposed on and in contact with the GaN material.

14. An enhancement mode gallium nitride (GaN) transistor having a voltage threshold at which the transistor turns ON, said enhancement mode transistor comprising:
a source electrode and a drain electrode;
a GaN material layer;
a gate structure having a gate metal disposed on said GaN material layer; and
a first hole injector/collector electrode disposed on said GaN material layer;
a second hole injector/collector electrode disposed on said GaN material layer;
wherein said first hole injector/collector electrode is configured to receive a positive voltage bias to inject holes into said GaN material layer and lower the voltage threshold, and said second hole injector/collector electrode is configured to receive a negative voltage bias to remove holes from said GaN material layer and raise the voltage threshold.

15. The enhancement mode transistor of claim 14, wherein said GaN material layer serves as both GaN gate material layer under the gate electrode, GaN hole injector/collector material layer under the first and second hole injector/collector electrodes, and as a connection from the GaN gate material layer to the hole collector electrode.

16. The enhancement mode transistor of claim 14, wherein the positive voltage bias is provided simultaneously with the negative voltage bias.

17. The enhancement mode transistor of claim 15, wherein the GaN material comprises an AlxGayIn_{(1-x-y)}N material.

18. The enhancement mode transistor of claim 17, wherein at least a portion of the AlxGayIn_{(1-x-y)}N material comprises a p-type dopant.

19. The enhancement mode transistor of claim 14, wherein said gate metal is directly disposed on and in contact with the GaN material layer, and said first and second hole injector/collector electrodes directly disposed on and in contact with the GaN material layer.

20. A transistor having a voltage threshold at which the transistor turns ON, said transistor comprising:
a source electrode and a drain electrode;
a gate structure having a gate metal disposed on a carrier material;
a first hole injector/collector electrode disposed on the carrier material; and
a circuit configured to detect the voltage threshold and apply a positive voltage bias to said first hole injector/collector electrode to inject holes into the carrier material to lower the voltage threshold, wherein a magnitude of the positive voltage bias is based on the detected voltage threshold whereby the larger the magnitude the more holes that are injected into the carrier material and the greater the voltage threshold is lowered.

21. The enhancement mode transistor of claim 20, wherein the circuit applies a first positive voltage bias to lower the voltage threshold a first amount, and applies a second positive voltage bias greater than the first positive voltage bias, to lower the voltage threshold a second amount greater than the first amount.

22. The transistor of claim 20, wherein the carrier material comprises GaN or pGaN material.

23. The transistor of claim 20, wherein said circuit comprises a silicon IC co-packaged with said transistor, or an integrated GaN chip.
